(19) United States
(12) Patent Application Publication
(10) Pub. No.: US 2015/0253849 A1
(43) Pub. Date: Sep. 10, 2015

(54) PIEZOELECTRIC OSCILLATION SUBSTRATE

(71) Applicant: Samsung Electro-Mechanics Co., Ltd., Suwon (KR)

(72) Inventors: Kyung-Lock KIM, Suwon (KR); Kyung-Mi Kim, Suwon (KR); Seung-Ho Lee, Suwon (KR); Jung-Wook Seo, Suwon (KR); Boum-Seock Kim, Suwon (KR)

(73) Assignee: Samsung Electro-Mechanics Co., Ltd., Suwon (KR)

(21) Appl. No.: 14/257,246

(22) Filed: Apr. 21, 2014

(30) Foreign Application Priority Data
Mar. 5, 2014 (KR) 10-2014-0026125

(51) Int. Cl. G06F 3/01; G06F 3/041; G06F 1/16; H01L 41/08

(52) U.S. Cl. CPC G06F 3/016; H01L 41/0825; G06F 3/041; G06F 1/16

(57) ABSTRACT

A piezoelectric oscillation substrate is disclosed. The piezoelectric oscillation substrate in accordance with an aspect of the present invention includes: a substrate body having a receiving groove formed on one surface thereof; an adhesive layer formed by being coated on a surface of the receiving groove; and a piezoelectric body being received in the receiving groove and adhered to the substrate body by the adhesive layer so as to generate vibrations in the substrate body.

### CROSS-REFERENCE TO RELATED APPLICATIONS

This application claims the benefit of Korean Patent Application No. 10-2014-0026125, filed with the Korean Intellectual Property Office on Mar. 5, 2014, the disclosure of which is incorporated herein by reference in its entirety.

### BACKGROUND

1. Technical Field

The present invention relates to a piezoelectric oscillation substrate.

2. Background Art

With the growing demand for improved implementation and operation of user interface, an increased number of display devices encompassing a touch window have been available. The touch window is a pointer input device that is similar to a mouse and is operated in link with a visual display terminal, such as LED or LCD.

With such a touch window, a pointer can be moved, and a desired instruction can be inputted through a particular motion, while the touch window is touched directly by a hand of by use of a dedicated input device such a stylus.

Such a touch window stimulates a user's senses, mostly visual and auditory senses, to allow for an intuitive use, and there has recently been a particular increase in devices that utilize the haptic technology, which uses the user's tactile sense.

The haptic technology is widely applied in devices such as mobile devices, monitors and television, which are installed with a display.

The related art of the present invention is disclosed in Korea Patent Publication No. 10-2012-0074832 (laid open on Jul. 6, 2012).

### SUMMARY

The present invention provides a piezoelectric oscillation substrate that can minimize defective attachment of a piezoelectric body and obtain a stronger oscillation property.

An aspect of the present invention provides a piezoelectric oscillation substrate that includes: a substrate body having a receiving groove formed on one surface thereof; an adhesive layer formed by being coated on a surface of the receiving groove; and a piezoelectric body being received in the receiving groove and adhered to the substrate body by the adhesive layer so as to generate vibrations in the substrate body.

The substrate body can be a touch board allowing information to be inputted by a touch contact.

The piezoelectric body can include: a piezoelectric element being vibrated by supplied electric power; an electrode coupled to the piezoelectric element so as to supply electric power to the piezoelectric element; and an electric wire inmolded in the substrate body and having one end thereof coupled to the electrode so as to supply electric power to the electrode.

The substrate body can have a touch area formed at a center portion thereof, and the piezoelectric body can be disposed along perimetric portions of the substrate body.

The piezoelectric body can be arranged at regular intervals in each of the perimetric portions of the substrate body.

The piezoelectric body can be adhered to the substrate body by having the adhesive layer coated on the receiving groove in a predetermined thickness and then having the piezoelectric body pressed against and attached to the adhesive layer.

The piezoelectric body can be pressed against and attached to the adhesive layer in such a way that an outer surface thereof corresponds to a surface of the substrate body.

According to an embodiment of the present invention, since the piezoelectric body is adhered to the substrate body while the piezoelectric body is received in the receiving groove, it is possible to minimize defective attachment of the piezoelectric body and obtain a stronger and more uniform oscillation property.

### BRIEF DESCRIPTION OF THE DRAWINGS

FIG. 1 is a cross-sectional view showing a piezoelectric oscillation substrate in accordance with an embodiment of the present invention.

FIG. 2 shows an example of oscillating waves transferred to a substrate body by a piezoelectric body in the piezoelectric oscillation substrate in accordance with an embodiment of the present invention.

FIG. 3 shows an example of the piezoelectric body arranged in the piezoelectric oscillation substrate in accordance with an embodiment of the present invention.

### DETAILED DESCRIPTION

Hereinafter, a certain embodiment of a piezoelectric oscillation substrate in accordance with the present invention will be described in detail with reference to the accompanying drawings. In describing the present invention with reference to the accompanying drawings, any identical or corresponding elements will be assigned with same reference numerals, and no redundant description thereof will be provided.

When one element is described to be “coupled” to another element, it does not refer to a physical, direct contact between these elements only, but it shall also include the possibility of yet another element being interposed between these elements and each of these elements being in contact with said yet another element.

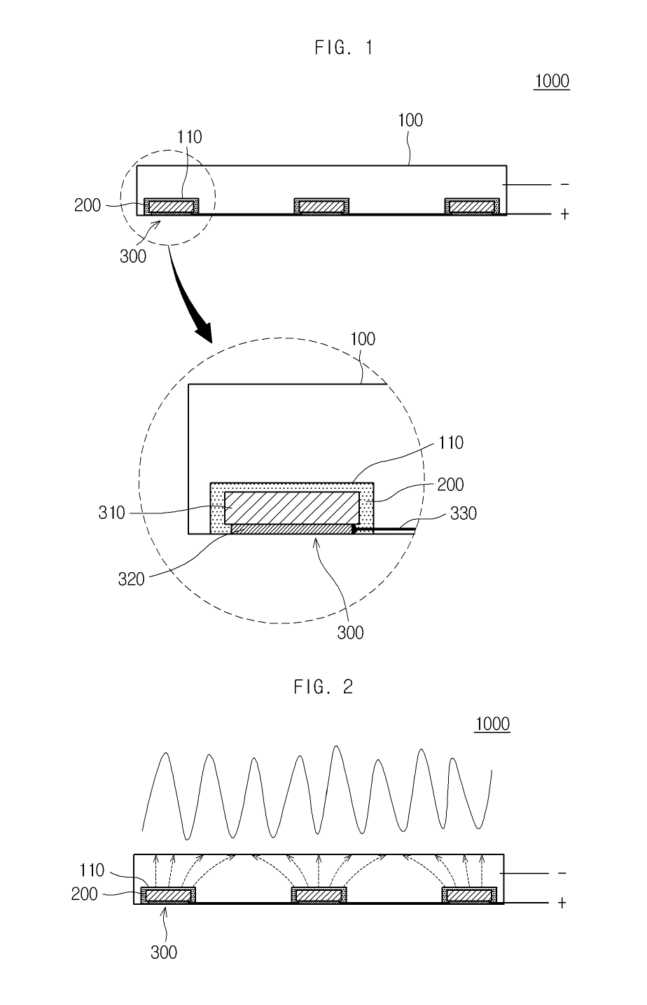

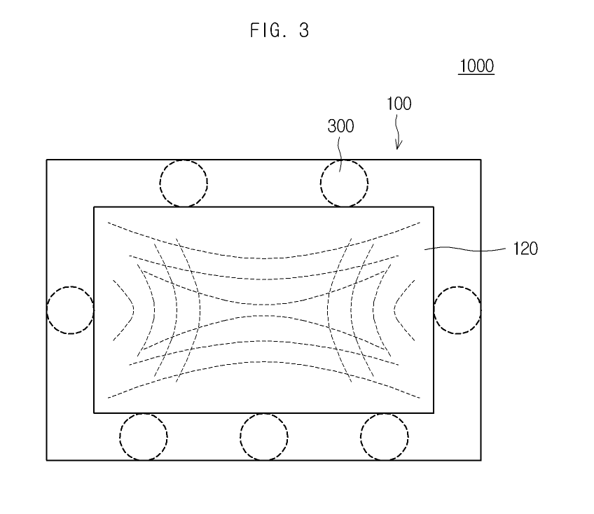

FIG. 1 is a cross-sectional view showing a piezoelectric oscillation substrate in accordance with an embodiment of the present invention. FIG. 2 shows an example of oscillating waves transferred to a substrate body by a piezoelectric body in the piezoelectric oscillation substrate in accordance with an embodiment of the present invention. FIG. 3 shows an example of the piezoelectric body arranged in the piezoelectric oscillation substrate in accordance with an embodiment of the present invention.

As illustrated in FIG. 1 to FIG. 3, a piezoelectric oscillation substrate 1000 in accordance with an embodiment of the present invention includes a substrate body 100, an adhesive layer 200 and a piezoelectric body 300.

The substrate body 100 is a portion having a receiving groove 110 formed on one surface thereof, and oscillation generated by the piezoelectric body 300 can be sensed by having the oscillation transferred to the substrate body 100. In such a case, the receiving groove 110 is a groove that is formed while injection-molding the substrate body 100 or through a post-process such as etching, and can receive the piezoelectric body 300.

The adhesive layer 200 is a portion that is formed by being coated on a surface of the receiving groove 110, and can have the piezoelectric body 300 attached to the substrate body 100. In such a case, the adhesive layer 200 can be made of a material, such as epoxy resin, which has fluidity and thus can be coated on the receiving groove 110 and which can be sintered at a particular plastic temperature after attaching the piezoelectric body 300.

The piezoelectric body 300 is a portion that is received in the receiving groove 110 so as to cause the substrate body 100 to vibrate and is adhered to the substrate body 100 by the adhesive layer 200. Accordingly, as vibrations occur in the piezoelectric body 300 itself, it is possible to generate vibrations in the substrate body 100 to which the piezoelectric body 300 is attached.

When the piezoelectric body 300 is adhered to the substrate body 100 through the adhesive layer 200, defective attachment may be occurred due to factors such as an eccentric force exerted to the piezoelectric body 300 or unevenness in thickness of the adhesive layer 200.

Moreover, the thicker the substrate body 100 is, it is more likely that the vibrations generated in the piezoelectric body 300 may not be strongly transferred to a surface of the substrate body 100.

Accordingly, since the piezoelectric oscillation substrate 1000 in accordance with the present embodiment has the piezoelectric body 300 adhered to the substrate body 100 while the piezoelectric body 300 is received in the receiving groove 110, it is possible to minimize the defective attachment of the piezoelectric body 300 and obtain a stronger and more uniform oscillation property.

That is, since the piezoelectric body 300 is adhered to the substrate body 100 within the receiving groove 110 and it is possible to minimize a relative twisting of the piezoelectric body 300 or excessive coating of a particular portion of the adhesive layer 200, the defective attachment of the piezoelectric body 300 can be minimized, and more uniform vibrations can be generated, as illustrated in FIG. 2.

Moreover, since the piezoelectric body 300 is disposed in the receiving groove 110 that is recessed into the substrate body 100, the distance by which the vibrations of the piezoelectric body 300 are transferred becomes relatively shorter, and thus stronger vibrations can be transferred to the surface of the substrate body 100.

Particularly, for a product such as a smart input pad that needs to have a minimal thickness of the piezoelectric oscillation substrate, it can be more effective to adhere the piezoelectric body 300 to the substrate body 100 while the piezoelectric body 300 is received in the receiving groove 110, as in the piezoelectric oscillation substrate 1000 in accordance with the present embodiment.

Here, the substrate body 100 can be a touch board enabling an input of information through a touch contact. Specifically, a user can input desired information by touching the substrate body 100 by use of a finger or a dedicated input device, such as a stylus, during which the user can sense the vibrations of the piezoelectric body 300.

As such, in the case where the substrate body 100 is the touch board, since the piezoelectric body 300 is adhered to the substrate body 100 while being received in the receiving groove 110, the vibrations of the piezoelectric body 300 can be delivered to the user more uniformly and strongly, making it more effective for an intuitive use by the user.

In the piezoelectric oscillation substrate 1000 in accordance with the present embodiment, the piezoelectric body 300 can include a piezoelectric element 310, an electrode 320 and an electric wire 330.

The piezoelectric element 310 is a portion that can be vibrated by supplied electric power, and is an element using crystal or piezoelectric ceramics that can generate voltage when mechanical stress is applied thereto and generate warpage when voltage is applied thereto. Accordingly, the piezoelectric element 310 has a property of changing the voltage when pressure is exerted thereto (i.e., piezoelectric effect) and expanding or contracting when voltage is otherwise exerted thereto.

Since the piezoelectric element 310 can convert electrical energy to mechanical energy, vibrations can be generated by supplying electric power to the piezoelectric element 310.

The electrode 320 is a portion that is coupled to the piezoelectric element 310 so as to transfer electric power to the piezoelectric element 310. The electrode 320 can be made of a metallic material such as silver that has a relatively high electric conductivity.

The electric wire 330 is a portion that is inmolded in the substrate body 100 and has one end thereof coupled to the electrode 320 so as to supply electric power to the electrode 320. As illustrated in FIG. 1, the electric wire 330 can be interposed between electrodes 320 of every piezoelectric body 300 and between an external electrode (not shown) and the electrode 320 of the outermost piezoelectric body 300.

In such a case, the electric wire 330 can be inmolded, as illustrated in FIG. 1, by injection-molding the substrate body 100 while the electric wire 330 is inserted therein.

Accordingly, the electric wire 330 can be integrally formed with the substrate body 100, and thus it is possible to prevent the electric wire 330 from being exposed and interfered or damaged when the piezoelectric oscillation substrate 1000 in accordance with the present embodiment is used.

In the piezoelectric oscillation substrate 1000 according to the present embodiment, the substrate body 100 can have a touch area 120 formed at a center portion thereof, and the piezoelectric body 300 can be disposed along perimetric portions of the substrate body 100. That is, as shown in FIG. 3, the piezoelectric body 300 can be disposed in the perimetric portions of the substrate body 100 by avoiding the touch area 120.

As the piezoelectric body 300 is disposed along the perimetric portions of the substrate body 100, circuit portions and circuit parts used in the piezoelectric oscillation substrate 1000 are not interfered by the perimetric portions of the substrate body 100 when being installed in the piezoelectric oscillation substrate 1000, and the touch area 120 used for drawing a figure or inputting a text is not interfered by the piezoelectric body 300, making it possible for the touch area 120 and the piezoelectric body 300 to optimally perform their intended functions.

Here, piezoelectric bodies 300 can be arranged at regular intervals in each of the perimetric portions of the substrate body 100. That is, as shown in FIG. 3, the plurality of piezoelectric bodies 300 arranged in each of the perimetric portions of the substrate body 100 can evenly divide a length of each perimetric portion and have an equal distance from each other.

Accordingly, the piezoelectric oscillation substrate 1000 in accordance with the present embodiment can have most effective vibrations by, for example, transferring even oscillating waves to an entire surface of the substrate body 100.

In the piezoelectric oscillation substrate 1000 in accordance with the present embodiment, the piezoelectric body 300 can be adhered to the substrate body 100 by having the piezoelectric body 100 pressed against and attached to the adhesive layer 200 after the adhesive layer 200 is coated on the receiving groove 110 in a predetermined thickness. In such a case, the adhesion of the piezoelectric body 300 can be made by pressing the piezoelectric body 300 toward the substrate body 100 by use of, for example, a separate pressing jig.

As such, by pressing and attaching the piezoelectric body 300 after the adhesive layer 200 is coated on the receiving groove 110 in a predetermined thickness, the piezoelectric body 300 can be adhered to the substrate body 100 more readily by the adhesive layer 200.

Here, the piezoelectric body 300 can be pressed against and attached to the adhesive layer 200 in such a way that an outer surface thereof corresponds to the surface of the substrate body 100. In other words, as shown in FIG. 1, a line extended from the outer surface of the piezoelectric body 300 can be aligned with the surface of the substrate body 100.

Accordingly, it becomes possible to minimize and optimize the thickness of the piezoelectric oscillation substrate 1000 without having the piezoelectric body 300 protruded out of the surface of the substrate body 100 or forming the receiving groove 110 unnecessarily too deeply.

Although a certain embodiment of the present invention has been described, it shall be appreciated that there can be a very large number of permutations and modification of the present invention by those who are ordinarily skilled in the art to which the present invention pertains without departing from the technical ideas and scope of the present invention, which shall be defined by the claims appended below.

It shall be also appreciated that many other embodiments than the embodiment described above are included in the claims of the present invention.

What is claimed is:

1. A piezoelectric oscillation substrate comprising:
a substrate body having a receiving groove formed on one surface thereof;
an adhesive layer formed by being coated on a surface of the receiving groove; and
a piezoelectric body being received in the receiving groove and adhered to the substrate body by the adhesive layer so as to generate vibrations in the substrate body.

2. The piezoelectric oscillation substrate of claim 1, wherein the substrate body is a touch board allowing information to be inputted by a touch contact.

3. The piezoelectric oscillation substrate of claim 2, wherein the piezoelectric body comprises:
a piezoelectric element capable of being vibrated by supplied electric power;
an electrode coupled to the piezoelectric element so as to supply electric power to the piezoelectric element; and
an electric wire inmolded in the substrate body and having one end thereof coupled to the electrode so as to supply electric power to the electrode.

4. The piezoelectric oscillation substrate of claim 3, wherein the substrate body has a touch area formed at a center portion thereof, and
wherein the piezoelectric body is disposed along perimetric portions of the substrate body.

5. The piezoelectric oscillation substrate of claim 4, wherein the piezoelectric body is arranged at every regular interval in each of the perimetric portions of the substrate body.

6. The piezoelectric oscillation substrate of claim 1, wherein the piezoelectric body is adhered to the substrate body by having the adhesive layer coated on the receiving groove in a predetermined thickness and then having the piezoelectric body pressed against and attached to the adhesive layer.

7. The piezoelectric oscillation substrate of claim 6, wherein the piezoelectric body is pressed against and attached to the adhesive layer in such a way that an outer surface thereof corresponds to a surface of the substrate body.
